(19) United States
(12) Patent Application Publication
(10) Pub. No.: US 2014/0055688 A1
(43) Pub. Date: Feb. 27, 2014

(54) POLARIZER RESISTIVE TOUCH SCREEN

(71) Applicant: Robert J. Petcavich, The Woodlands, TX (US)

(72) Inventor: Robert J. Petcavich, The Woodlands, TX (US)

(73) Assignee: UNIPIXEL DISPLAYS, INC., The Woodlands, TX (US)

(21) Appl. No.: 13/980,272

(22) PCT Filed: Oct. 25, 2012
(86) PCT No.: PCT/US2012/061766

§ 371 Date: Jul. 17, 2013

Related U.S. Application Data
(60) Provisional application No. 61/551,124, filed on Oct. 25, 2011.

(51) Int. Cl. G02F 1/1333; G01R 27/02

(52) U.S. Cl. CPC G02F 1/13338; G01R 27/02
USPC 349/12; 324/691; 427/97.3; 427/97.4; 427/535; 427/560; 427/532

(57) ABSTRACT

Touch screen structures may have an on cell resistive touch sensor made up of a a polarizer film or analyzer. The polarizer film has a first high resolution grid pattern printed on it by at least one master plate and a second flexible, optically isotropic transparent substrate carrying a second high resolution pattern may also be used and assembled to the first pattern. The patterns are plated with conductive material and assembled so that the first and the second conductive patterns engage when the substrate is pressed.

### CROSS-REFERENCE TO RELATED APPLICATION

The present application claims priority to U.S. Provisional Patent Application No. 61/551,124, filed on Oct. 25, 2011 (Attorney Docket No. 2911-02500); which is hereby incorporated herein by reference.

### BACKGROUND

Touch-sensitive displays such as those found on portable and stationary electronics may be resistive touch screens. When pressure by a finger, stylus, or other appendage is applied to a resistive touch screen two flexible substrates coated with a resistive material are pressed together and the horizontal and vertical lines that are respectively located on the two substrates make contact, the location of the touch is registered.

### SUMMARY

In an embodiment, a method for manufacturing a resistive touch sensor circuit comprising: printing, by a first master plate using a first ink, a first pattern on a first side of a substrate, and wherein the first pattern comprises a first plurality of lines; depositing at least one layer of a conductive material on the first pattern, wherein the layer is deposited by electroless plating; printing, by a second master plate using a second ink, a second pattern on the first side of the first substrate, and wherein the second pattern comprises a second plurality of lines; depositing at least one layer of the conductive material on the second pattern, wherein the layer is deposited by electroless plating; printing, by a third master plate using a third ink, on at least one of the first or the second patterns, a plurality of spacer dots.

In an embodiment, a resistive touch sensor comprising: a first substrate and a second substrate, wherein the first substrate comprises a polarizer film, wherein a first plurality of lines are printed by a first master plate on a first side of the first substrate, and wherein a set of spacers are printed by a second master plate on the first side of the first substrate; wherein the second substrate comprises an optically isotropic transparent film, wherein a second plurality of lines are printed by a third master plate on a first side of the second substrate; wherein the first and the second substrates each comprise an x and a y axis along a surface plane of the first sides that contain the first and the second pluralities of lines; wherein the first plurality of lines is printed along the x-axis of the first substrate, and wherein the second plurality of lines is printed along the y-axis of the second substrate; plating the first and the second plurality of lines by electroless plating; and an adhesive promoting agent, wherein the adhesive promoting agent is disposed between the first side of the first substrate and first side of the second substrate, and wherein the first and the second substrates are assembled to form an x-y grid.

In an embodiment, a display system comprising: a liquid crystal display unit; a resistive touch sensor comprising: an inner and an outer surface, wherein the inner surface is disposed on the second glass substrate; wherein the resistive touch sensor further comprises a first substrate comprising a first set of conductive lines, a polarizer film, a plurality of spacer dots, and a second substrate comprising a second set of conductive lines; and wherein the first and the second set of printed lines are printed using a flexographic printing process and wherein the first and the second set of printed lines are plated with conductive material in an electroless plating process.

### BRIEF DESCRIPTION OF THE DRAWINGS

For a detailed description of exemplary embodiments of the invention, reference will now be made to the accompanying drawings in which:

FIG. 1 is a schematic an embodiment of a touch screen configuration.

FIG. 2 is an alternate embodiment touch screen configuration.

FIGS. 3A-3C are isometric and cross-sectional views of embodiments of flexo-master patterns.

FIGS. 4A-4B are top views of embodiments of flexo-master patterns.

FIGS. 5A-5B are isometric and cross-sectional views of embodiments of a resistive touch sensor.

FIG. 6 is an illustration of an embodiment of a method of manufacturing touch sensor fabrication process

FIGS. 7A-7B are embodiments of methods of high precision ink metering systems.

FIGS. 8A-8B are illustrations of a top view of a printed touch sensor circuit with spacers.

FIG. 9 shows the top views a black matrix and a touch sensor.

FIG. 10 is an illustration of an embodiment of an isometric view of the touch screen configuration.

FIG. 11 is an embodiment of a method of manufacturing a resistive touch screen sensor.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

A touch screen display may comprise a liquid crystal display unit and a resistive touch sensor, where the liquid crystal display unit comprises a lighting system, wherein the lighting system comprises a light source, enhancement films, at least one light guide, at least one diffuser plate, a first glass substrate disposed on the light source, a thin film transistor disposed on the first glass substrate and a plurality of liquid crystal cells. In this example, a color filter is disposed on the plurality of liquid crystal cells wherein the color filter comprises a red-green-blue filter and wherein a black matrix is embedded in the RGB filter, and wherein a second glass substrate is disposed on the RGB filter.

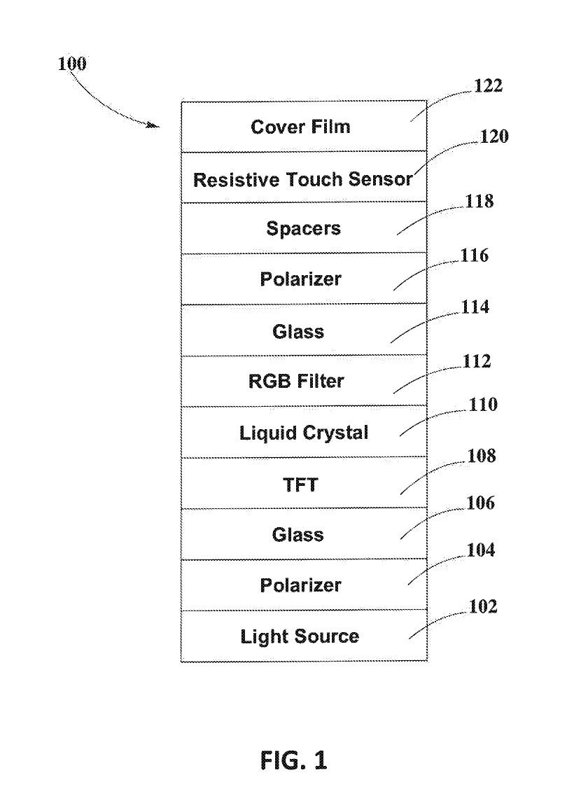

FIG. 1 is an illustration of a touch screen configuration. The structure 100 includes a light source 102. The light source may be a backlight, backlights are one source of illumination used in touch screens; the backlight may be the first layer from the back. A common backlight may include a light source, enhancement films, light guides and diffuser plates. The light sources used may be, for example, electroluminescent panels (ELP), Cold cathode fluorescent lamps (CCFL), hot cathode fluorescent lamps (HCFL), woven fiber optic mesh, incandescent lamps, and light emitting diodes (LED). The light guides and diffuser plates together with other accessories of a light source which may also be referred to as a light source 102 create a uniform distribution of the light emitted from the light source to first polarizer film 104. First polarizer film 104 may be disposed on the light source 102 and polarizes the light beams emitted by light source 102 and passes only light with certain linear polarization. Polarizers may be made of highly uniaxially oriented polymeric materials containing dichroic dye molecules or crystals. High dichroic ratio polarizers which may have the necessary optical performance to be used in various liquid crystal applications may be composed of thin polyvinyl alcohol (PVA) film containing elongated iodine complexes. Such polarizers may require a high molecular order for the absorbing material, this order may be achieved by the adsorption of the dye into a stretched film of PVA. These dichroic polarizers may be based on dichroic materials with a rod-like molecular or crystalline structure whose long molecular or crystal axis is almost parallel to the transition moment of the light absorption.

In an embodiment, the polymer may absorb dichroic liquid so the iodine ions or dye ions extend into the inside of the polymer. The polymer may be heated and stretched so that it becomes a PVA membrane. The light penetration may be about 5% to view the light penetration under desirable conditions. The other 95% of the light may be refracted, reflected or absorbed by the layers of the film. Polarizers may absorb the light polarized along the long molecular axis and may transmit most of the light polarized in all directions orthogonal to this axis. The absorption rate and the transmittance of the dichroic polarizers may be two factors that affect the brightness of liquid crystal displays (LCDs). Since the mechanical properties, like resistance temperature and humidity, of the polarizer may be poor, films of triacetyl cellulose (TAC) may be used to protect the polarizing layer. The body of iodine polarizing film may be coated with TAC protective film on the upper and lower sides, the protective layers may have a thickness of approximately 200 microns.

Turning back to FIG. 1, a first glass substrate or layer 106 is disposed on polarizer 104 and thin film liquid crystal layer 110 is disposed between a thin film transistor layer 108 (TFT) and RGB (red green and blue) filter 112. First glass substrate 106 and a second glass substrate 114 encapsulate the liquid crystals cells, where a second glass substrate 114 is disposed on top of the RGB filter.

In an embodiment (not pictured), a primary three color pattern (red, green and blue) is formed over a black matrix. In the embodiment, this black matrix of chrome or resin may be previously formed on second glass substrate 114, for example, to prevent leakage of backlight and color crosstalk from adjacent pixels, prior to deposition of a substantially transparent conductive touch sensor. In some embodiments, an indium tin oxide film (ITO) is used. A second polarizer 116 may be disposed on top of second glass substrate 114. This second polarizer 116 may also be referred to as an analyzer. The direction of the polarization used by the analyzer may be perpendicular to the direction of polarization of first polarizer film 104.

Resistive touch sensor 120 may be placed over second polarizer 116. The touch sensor 120 and the second polarizer 116 may be separated by a plurality of spacers 118 that may be referred to as spacer dots that also protect touch sensor 120 from electromagnetic interference. In an embodiment, the plurality of spacer dots have a diameter of 1 micron-25 microns and a height of 1 micron-25 microns. Preferably, the plurality of spacer dots have a diameter of 5 microns-10 microns, and a height of 3 microns-5 microns. In an embodiment, indium Tin Oxide (ITO) may be used for touch screen sensor applications as resistive touch sensor 120 as it is optically transparent and is a conductor. In resistive touch screens, when a user touches the screen with a finger or a stylus, the ITO film may be pushed into contact with the ITO glass producing a voltage signal. A processor processes the signal to compute the coordinates (X and Y) of the touch event and process the appropriate response to the touch point. Touch screens may include cover film 122 to protect and isolate the device from environmental conditions and protect against abrasion, normal wear, oxygen and other harmful chemical agents. The protective cover film may be, for example, a polyester (PET) film.

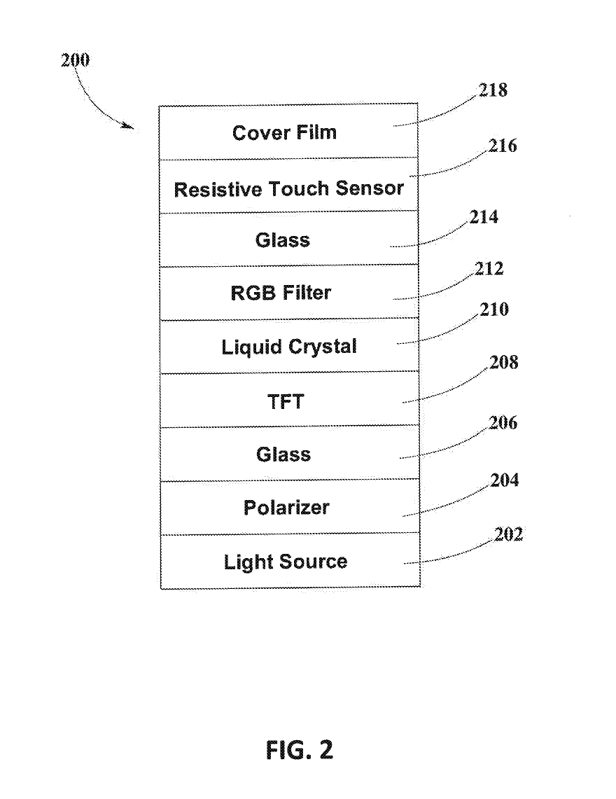

FIG. 2 is an illustration of an embodiment of a touch screen module structure 200. In FIG. 2, the touch screen structure 200 may comprise a light source 202 that may generate light beams that may be polarized in one linear direction by first polarizer 204. Liquid crystal cells 210 may be disposed between TFTs 208 and RGB filter 212. Glass substrate 206 and glass substrate 214 encapsulate the liquid crystals cells. Glass substrate 206 carries TFTs 208 and glass substrate 214 carries RGB filter 212. In an embodiment, a primary three color pattern (red, green and blue) may be formed formed over a black matrix. In the embodiment, the black matrix of chrome or resin may be formed on glass substrate 214, to prevent leakage of backlight and color crosstalk from adjacent pixels. An indium tin oxide (ITO) film (not pictured) may be deposited on the color pattern subsequent to the formation of the pattern over the black matrix.

A resistive touch sensor 216 may be disposed on glass substrate 214. Touch sensor 216 may be formed by conductive lines printed on one side of a polarizer film, by means of a roll to roll process. This pattern of lines may be referred to as a conductive microstructural pattern, which may comprise a conductive material patterned on a non-conductive substrate where the conductive material is less than 50 μm wide along the printing plane of the substrate.

Comparing FIG. 1 and FIG. 2, the resistive touch sensor 216 built on a flexible polarizer film may substitute for the touch sensor 120, second polarizer 116 film, and spacers 118. Materials and components located between the two polarizers of an LCD may be optically isotropic. An LCD functions by orienting light into certain polarities, and any material which diffuses, refracts, or changes the polarity of light will reduce the performance of the LCD. Glass and some polycarbonates are examples of optically isotropic materials. Some touch screens may include cover film 218 to protect and isolate the device from environment conditions and protect against abrasion, normal wear, oxygen and other harmful chemical agents. Generally, polyester (PET) film with a clear/hard coating is employed as a protective cover layer in touch screen panels. Alternatively, in some embodiments a hard coating (not pictured) may be applied directly on the outer surface of resistive touch sensor 216 to substitute for cover film 218. The hard coating may be a highly crosslinked acrylic-coated film. A specially formulated UV curable coating solution (not pictured) comprising mono and multifunctional acrylic monomers and acrylic oligomers may be applied to one or both sides of touch sensor 216. The coating application methods may include but are not limited to dip coating, slot die and roll to roll printing. The high density cross-linked polymer structures formed by the cross linking of monomer chains within the coating solution may create a coating layer with a thickness from, for example, 5 to 50 microns. The coating layer may have a pencil hardness up to about 6 H.

Flexography is a form of a rotary web letterpress where relief plates are mounted on to a printing cylinder, for example, with double-sided adhesive. These relief plates, which may also be referred to as a master plate or a flexoplate, may be used in conjunction with fast drying, low viscosity solvent, and ink fed from anilox or another two roller inking system. The ink may be combination of monomers, oligomers and/or polymers, metal elements metal elements complexes and/or organometallics in liquid state that is discretely applied over a substrate surface and the anilox roll may be a cylinder used to provide a measured amount of ink to a printing plate. The master plate may be any roll carrying a predefined pattern used to print on any substrate. The anilox roll may be a cylinder used to provide a measured amount of ink to a printing plate. The ink may be, for example, water-based or ultraviolet (UV)-curable inks. In one example, a first roller transfers ink from an ink pan or a metering system to a meter roller or anilox roll. The ink is metered to a uniform thickness when it is transferred from the anilox roller to a plate cylinder. When the substrate moves through the roll-to-roll handling system from the plate cylinder to the impression cylinder, the impression cylinder applies pressure to the plate cylinder which transfers the image on to the relief plate to the substrate. In some embodiments, there may be a fountain roller instead of the plate cylinder and a doctor blade may be used to improve the distribution of ink across the roller.

Flexographic plates may be made from, for example, plastic, rubber, or a photopolymer which may also be referred to as a UV-sensitive polymer. The plates may be made by laser engraving, photomechanical, or photochemical methods. The plates may be purchased or made in accordance with any known method. The preferred flexographic process may be set up as a stack type where one or more stacks of printing stations are arranged vertically on each side of the press frame and each stack has its own plate cylinder which prints using one type of ink and the setup may allow for printing on one or both sides of a substrate. In another embodiment, a central impression cylinder may be used which uses a single impression cylinder mounted in the press frame. As the substrate enters the press, it is in contact with the impression cylinder and the appropriate pattern is printed. Alternatively, an inline flexographic printing process may be utilized in which the printing stations are arranged in a horizontal line and are driven by a common line shaft. In this example, the printing stations may be coupled to curing stations, cutters, folders, or other post-printing processing equipment. Curing may refer to the process of drying, solidifying or fixing any coating or ink imprint, previously applied, on a substrate. Other configurations of the flexo-graphic process may be utilized as well.

In an embodiment, flexo plate sleeves may be used, for example, in an in-the-round (ITR) imaging process. In an ITR process, the photopolymer plate material is processed on a sleeve that will be loaded on to the press, in contrast with the method discussed above where a flat plate may be mounted to a printing cylinder, which may also be referred to as a conventional plate cylinder. The flexo-sleeve may be a continuous sleeve of a photopolymer with a laser ablation mask coating disposed on a surface. In another example, individual pieces of photopolymer may be mounted on a base sleeve with tape and then imaged and processed in the same manner as the sleeve with the laser ablation mask discussed above. Flexo-sleeves may be used in several ways, for example, as carrier rolls for imaged, flat, plates mounted on the surface of the carrier rolls, or as sleeve surfaces that have been directly engraved (in-the-round) with an image. In the example where a sleeve acts solely as a carrier role, printing plates with engraved images may be mounted to the sleeves, which are then installed into the print stations on cylinders. These pre-mounted plates may reduce changeover time since the sleeves can be stored with the plates already mounted to the sleeves. Sleeves are made from various materials, including thermoplastic composites, thermoset composites, and nickel, and may or may not be reinforced with fiber to resist cracking and splitting. Long-run, reusable sleeves that incorporate a foam or cushion base are used for very high-quality printing. In some embodiments, disposable “thin” sleeves, without foam or cushioning, may be used.

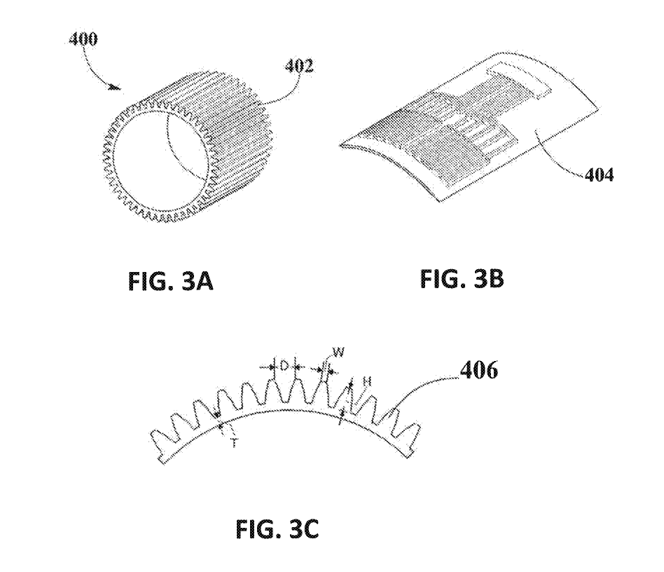

FIGS. 3A-3C shows embodiments of flexo-masters. As noted above, the terms “master plate” and “flexo-master” may be used interchangeably. FIG. 3A is an isometric view of a straight line cylindrical flexo-master 400 with a pattern 402 comprising a plurality of lines. FIG. 3B is an illustration of an isometric view of an embodiment of circuit pattern flexo-master 404 that has a different geometry than the straight lines of FIG. 3A. FIG. 3C is a cross sectional view of a plurality of lines 406 of the patterned flexomaster as shown in FIG. 3A which may also be referred to as protrusions in a cross-sectional view. The “W” shown in FIG. 3C is the width of the flexo-master protrusions, “D,” is the distance between the center points of the protrusions 406 and “H” is the height of the teeth. In some embodiments, the dimensions D, W, and H may be uniform across the flexo-master, while in other embodiments, dimensions D, W, and H may vary across the flexo-master. In some implementation, width W of flexo-master teeth is between 3 and 5 microns, distance D between adjacent teeth 1 and 5 mm, height H of the teeth may vary from 3 to 4 microns and thickness T of the teeth is between 1.67 and 1.85 mm. In an embodiment, printing may be performed on one side of a substrate, for example, using one roll comprising both patterns, or by two rolls each comprising one pattern, with the substrate subsequently being cut and assembled. In an alternate embodiment, both sides of a substrate may be printed, for example, using two different print stations and two different flexo-masters. Flexo-masters may be used, for example, because printing cylinders may be expensive and hard to change out, which would make the cylinders efficient for high-volume printing but may not make that system desirable for small batches or unique configurations. Changeovers may be costly due to the time involved. In contrast, flexographic printing may mean that ultraviolet exposure can be used on the photo plates to make new plates that may take as little as an hour to manufacture. In an embodiment, using the appropriate ink with these flexo-masters may allow the ink to be loaded from, for example, a reservoir or a pan in a more controlled fashion wherein the pressure and surface energy during ink transfer may be able to be controlled. The ink used for the printing process may have properties such as adhesion and UV-curability as well as a catalytic so that the ink stays in place when printed and does not run, smudge, or otherwise deform from the printed pattern, and wherein the ink joins together to form the desired features and may comprise a catalyst that is conducive to plating, for example, electroless plating. Electroless plating is a catalyst activated chemical technique used to deposit a layer of conductive material on to a given surface. A plating catalyst may be a substance that enables a chemical reaction in the plating process. In some embodiments this substance may be contained in the printing ink. Each pattern may, for example, be made using a recipe wherein the recipe comprises at least one flexo-master and at least one type of ink. Different resolution lines, different size lines, and different geometries, for example may require different recipes. Different inks may be used with different rolls and in some embodiments multiple rolls may be used to print a single pattern.

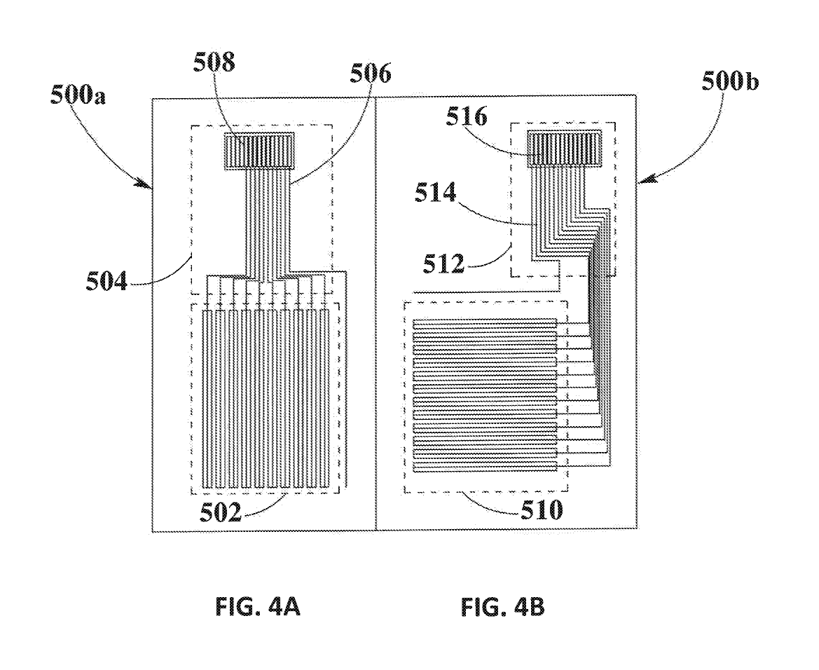

FIGS. 4A and 4B are illustrations of a top view of a flexo-master. In FIG. 4A, a top view at 500a is of a first pattern to be printed on one side of a thin flexible transparent substrate. A first pattern such as 500a may be printed on one side of a first flexible substrate. The pattern 500a comprises a plurality of lines 502 that may constitute the Y-oriented segment of an X-Y grid. The tail 504 comprises electrical leads 506 and electrical connectors 508. FIG. 4B depicts an embodiment of a second pattern 500b which may be printed on one side of a second flexible substrate. The second pattern 500b comprises a plurality of lines 510 that may constitute the X oriented segment of an X-Y grid (not pictured). Tail 512 comprises electrical leads 514 and electrical connectors 516.

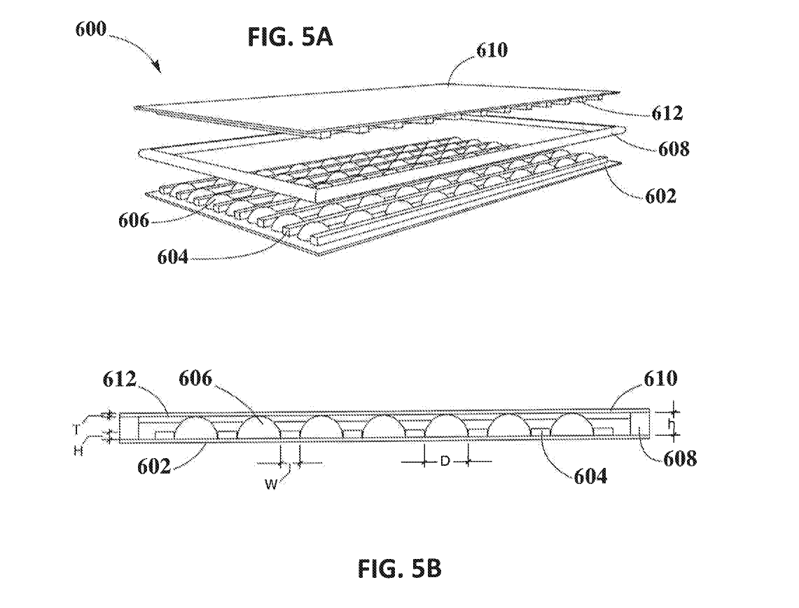

FIGS. 5A-5B are illustrations of an isometric view and a cross-section of a resistive touch sensor structure. FIG. 5A shows an isometric view 600 of resistive touch sensor 216. FIG. 5B illustrates a cross-sectional view of resistive touch sensor 216 comprising a first plurality of conductive lines 604 and a plurality of spacer dots 606 disposed on a first substrate, polarizer film 602, a second plurality of conductive lines 612 is disposed on second substrate 610 and adhesive promoting agent 608, bonding polarizer film 602 and second substrate 610, where second substrate 610 is an optically isotropic transparent film. In FIG. 5B, the plurality of spacer dots 606 may be disposed in an alternating fashion with each line of the first plurality of conductive lines 604. Materials used to form the conductive lines may comprise copper (Cu), silver (Ag), gold (Au), nickel (Ni), tin (Sn) and Palladium (Pd). Depending on the resistivity of the materials used for the circuit, the circuit may have different response times and power requirements.

In some embodiments, the circuit lines may have a resistivity between 0.005 micro Ohms per square and 500 Ohm per square and response times in a range between nanoseconds and picoseconds. It is understood that “ohms per square” means the square formed by the assembly of the two patterns, wherein one In general, with the above metal configuration, circuits consuming 75% less power (or more in some embodiments) than those using ITO (Indium Tin Oxide) may be achieved. In one particular embodiment the width W of the printed electrodes varies from 5 to 10 microns with a tolerance of +/−10%. The spacing D between the lines may vary from about 1 mm to 5 mm. For optimal optical performance the conductive patterns should approximately match the size and shape of the display's black matrix. Hence, spacing D and width W are functions of the size of the black matrix of the display. Height H may range from about 6 nanometers to about 150 microns. Height h of adhesive promoting agent 608 and the plurality of spacer dots 606 may be 500 nanometers or more, depending on the height H of the conductive lines. In an embodiment, the height of the adhesive promoting agent 608 and the height of the plurality of spacer dots 606 are not the same. Polarizer film 602 and second substrate 610 may have a thickness T between 1 micron and 1 millimeter and a surface energy from 20 dynes per centimeter (D/cm) to 90 D/cm.

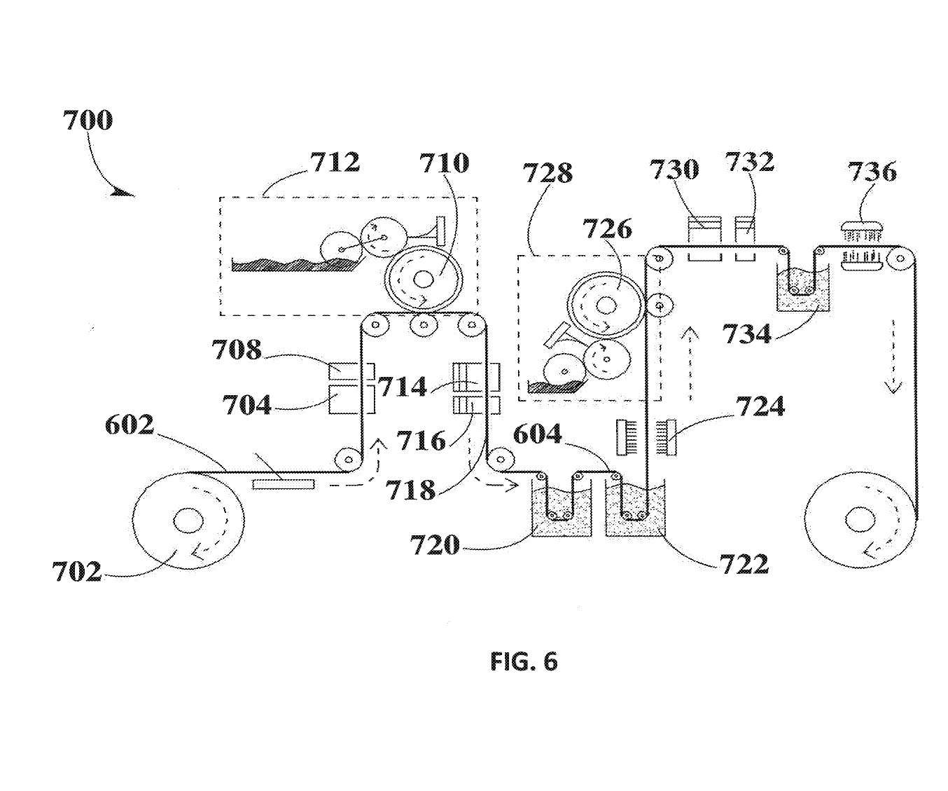

FIG. 6 is an embodiment of a method of fabrication of a resistive touch sensor. FIG. 6 illustrates method 700 used to fabricate the resistive touch sensor 216 in FIG. 2. An elongated, flexible, thin polarizer film 602 is placed on unwind roll 702. Transparent substrates such as PET (polyethylene terephthalate), polyester and polycarbonate may be used as the substrate 602. The thickness of polarizer film 602 should be small enough to avoid excessive stress during flexing of the touch sensor. A thin polarizer film may improve optical transmissivity. On the other hand, the thickness of polarizer film 602 should not be so small as to jeopardize the continuity of this layer or its material properties during the manufacturing process. Preferably, a thickness between 1 micron and 1 millimeter may be suitable. Turning back to the method 700, polarizer film 602 is transferred, for example, via any known roll to roll handling method, from unwind roll 702 to first cleaning station 704. As the roll to roll process involves a flexible material, the alignment of features can be somewhat challenging. Given that printing high resolution lines is an important feature of the process, precision in maintaining the right alignment is important. In one embodiment, positioning cable 706 is used to maintain proper alignment of the features, in other embodiments any known means may be used for this purpose. In some embodiments first cleaning system 704 comprises a high electric field ozone generator. Ozone generated is used to remove impurities, like oils or grease, from polarizer film 602.

Then polarizer film 602 may go through second cleaning system 708. In this particular embodiment second cleaning system 708 may comprise a web cleaner. A web cleaner is any device used in web manufacturing to remove particles from a web or substrate. After these cleaning stages, polarizer film 602 goes through a first printing process where a microscopic pattern is printed on one of the sides of polarizer film 602. The microscopic pattern is imprinted by master plate 710 using UV curable ink that may have a viscosity between 200 and 2000 cps. Further, the microscopic pattern may be formed by lines having a width between 2 and 35 microns. In an embodiment, this pattern may be similar to the first pattern shown in FIG. 5. In an embodiment, a plurality of rolls may be used to print the pattern (not pictured) and the plurality of rolls may use different inks, similar inks, or the same ink. The ink type used may depend on the geometry and complexity of the features of the pattern because the pattern may comprise a plurality of lines with different thicknesses, connecting features, geometries of connecting features, and cross-sectional geometries.

The amount of ink transferred from master plate 710 to polarizer film 602 may be regulated by high precision metering system 712. The amount of ink transferred may depend on the speed of the process, ink composition, and the shape and dimensions of the plurality of lines that comprise the pattern. The speed of the machine may vary from 20 feet per minute (fpm) to 750 fpm, while 50 fpm to 200 fpm may be suitable for some applications. The ink may contain plating catalysts. The first printing process may be followed by a curing step. The curing may comprise ultraviolet light curing 714 with target intensity from about 0.5 mW/cm2 to about 50 mW/cm2 and wavelength from about 280 nm to about 480 nm, in addition it may comprise oven heating 716 module that applies heat within a temperature range of about 20° C. to about 85° C. After the curing step, a plurality of patterned lines 718 are formed on top of the polarizer film 602.

With a printed microscopic pattern on one side, polarizer film 602 may be exposed to electroless plating 720. In this step a layer of conductive material is deposited on the microscopic pattern. This may be accomplished by submerging first patterned lines 718 of polarizer film 602 into electroless plating at plating station 720 in a tank that contains copper or other conductive material in a liquid state at a temperature range between 20 and 90° C., with 80° C. being applied in some embodiments. Alternatively, the conductive material may comprise at least one of silver (Ag), gold (Au), nickel (Ni), tin (Sn), and Palladium (Pd). The deposition rate is normally about 10 nanometers per minute and deposits the conductive material to a thickness of about 0.001 microns to about 100 microns, depending on the speed of the web and according to the application. This electroless plating process does not require the application of an electrical current and it only plates the patterned areas containing plating catalysts that were previously activated by the exposure to UV radiation during the curing process. The plating bath may include powerful reducing agents, such as borohydride or hypophosphite, which cause the plating to occur. The plating thickness resulting from electroless plating may be more uniform compared to electroplating due to the absence of electric fields. Although electroless plating may be more time consuming than electrolytic plating, electroless plating may be well suited for parts with complex geometries and/or many fine features such as those that may be present in a high resolution conducting pattern. After the plating at plating station 720, first conductive lines 604 are formed on top of polarizer film 602.

Washing process 722 follows electroless plating at plating station 720. After the plating 720, polarizer film 602 may be cleaned by being submerged into a cleaning tank that contains water at room temperature and are then dried at drying station 724 in which polarizer film 602 is dried by the application of air at room temperature. In another embodiment, a passivation step in a pattern spray may be added after the drying step to prevent any dangerous or undesired chemical reaction between the conductive materials and water.

The drying at drying station 724 may be followed by the creation of the plurality of spacer dots 606. A pattern of microstructural spacers is printed on the first side of polarizer film 602. The pattern is printed by second master plate 726 using UV curable ink that may have a viscosity between 200 and 2000 cps. The amount of ink transferred from second master plate 726 to polarizer film 602 is regulated by high precision metering system 728 and depends on the speed of the process, ink composition and patterns shape and dimension. The ink used to print the plurality of spacer dots 606 may consist of organic-inorganic nanocomposites utilizing methyl tetraethylorthosilicate or glycidopropyltrimetoxysilane as network formers hydrolyzed using hydrochloric acid. Silica sols, silica powders, ethyl cellulose and hydroxypropyl may be utilized as additives to adjust viscosity. The ink may also include a commercially available photoinitiator, such as Cyracure, Flexocure or Doublecure, allowing the use of ultraviolet light curing. The plurality of spacer dots 606 may be enhanced optically by nano-particle metal oxides and pigments such as titanium dioxide (TiO2), barium titanium dioxide (BaTiO), silver (Ag), nickel (Ni), molybdenum (Mo) and platinum (Pt). The index of refraction of the dots preferably will match optically the index of refraction of first conductive lines 604. Nano-particles can also be used to adjust the viscosity of the ink. Furthermore, the shrinkage during curing may be reduced by the incorporation of nanoparticle leads to the ink. Following the second printing process polarizer film 602 may go through a second curing step, comprising ultraviolet light curing 730 with an intensity from about 0.5 mW/cm2 to 20 mW/cm2 and/or oven drying 732 at a temperature between 20° C. and 150° C. The plurality of spacer dots 606 may have a radius between 80 microns and 40 microns and a height between 500 nanometers and 15 microns. Subsequently, polarizer film 602 may go through second washing process 734, using known conventional washing techniques, then polarizer film 602 may be dried using air at room temperature in at drying station 736.

In a parallel process, following similar steps, second conductive lines 612 may be created on one side of second substrate 610. This substrate may be an optically isotropic transparent film such as cellulose triacetate, acrylic, or similar polymers. Alternatively, spacer dots may also be printed on second substrate 610 in a similar manner as disclosed above.

When both conductive patterns have been printed and plated, the resistive touch sensor may be assembled. First, a layer of adhesive promoting agent 608 may be applied on a polarizer film 602 surrounding the first plurality of conductive lines 604, having a layer thickness of more than 500 nanometers, in some embodiments. Then second substrate 610 that has the second plurality of conductive lines 612 is bonded to polarizer film 602, in such a way that both conductive patterns are aligned, facing each other and separated by the small gap created by spacer dots 606 and adhesive promoting agent 608. The resulting structure would be an X-Y matrix resistive touch sensor, where each of the intersections of the conductive lines forms a normally open push button switch, as illustrated in FIG. 6.

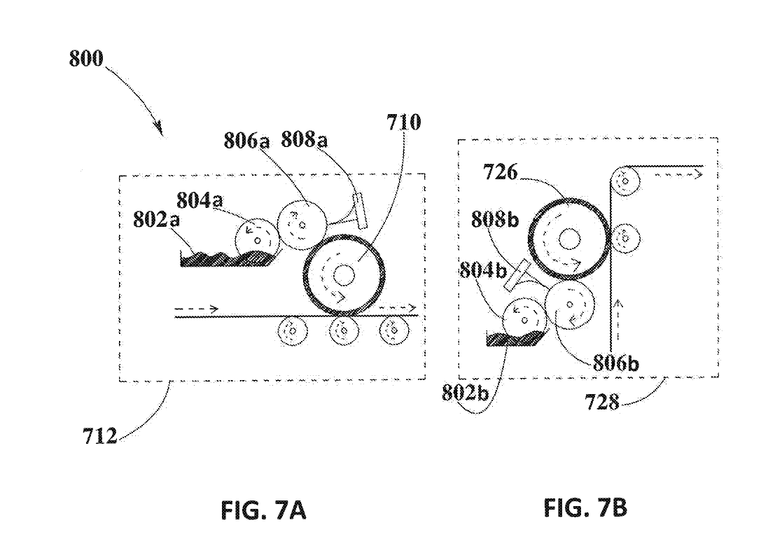

FIGS. 7A and 7B are embodiments of a high precision metering system 712 and high precision metering system 728 which control the exact amount of ink that is transferred to polarizer film 602 by master plate 710 and second master plate 726 as described in both printing steps of manufacturing method 700 in FIG. 7. FIG. 7B represents an embodiment of a system for printing first patterned lines 718 and FIG. 7A is an embodiment of a system for printing spacer dots 606. The system in FIG. 7A may comprise an ink pans 802a, a transfer roll 804a, an anilox roller 806a, a doctor blade 808a and 710. In FIG. 7A a portion of the ink contained in ink pan 802 is transferred to anilox rollers 806, usually constructed of a steel or aluminum core which is coated by an industrial ceramic whose surface contains millions of very fine dimples, known as cells. Depending on the design of the printing process, anilox rollers 806 may be either semi-submersed in ink pans 802 or come into contact with a metering roll. Doctor blades 808 are used to scrape excess ink from the surface leaving just the measured amount of ink in the cells. The roller then rotates to contact with the flexographic printing plates, for example, master plate 710, which receives the ink from the cells for transfer to polarizer film 602. The rotational speed of the printing plates may match the speed of the web, which may vary between 20 fpm and 750 fpm. In FIG. 7B a portion of the ink contained in ink pan 802 is transferred to anilox rollers 806, usually constructed of a steel or aluminum core which is coated by an industrial ceramic whose surface contains millions of very fine dimples, known as cells. Depending on the design of the printing process, anilox rollers 806 may be either semi-submersed in ink pans 802 or come into contact with a metering roll. Doctor blades 808 are used to scrape excess ink from the surface leaving just the measured amount of ink in the cells. The roller then rotates to contact with the flexographic printing plates, for example, master plate 726, which receives the ink from the cells for transfer to polarizer film 602. The rotational speed of the printing plates may match the speed of the web, which may vary between 20 fpm and 750 fpm.

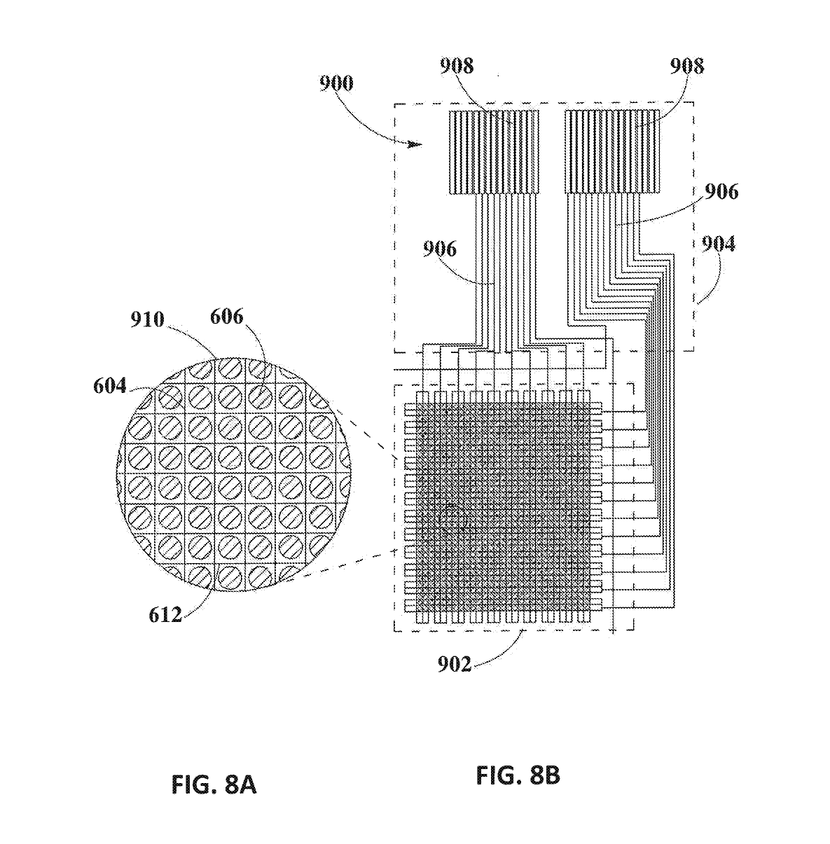

FIG. 8A depicts an enlarged view 910 in which spacer dots 606 and the X-Y grid, formed by first conductive lines 604 and second conductive lines 612 are shown. FIG. 8B is an embodiment of a top view 900 of the resistive touch sensor 216 built on flexible polarizer film 602 in accordance with various embodiments. Shown in this figure are conductive grid lines 902 and tail 904 comprising electrical leads 906 and electrical connectors 908. These conductive lines form an x-y grid that enables the recognition of the point where the user has interacted with the sensor. This grid may have 16×9 conductive lines or more and a size range from 2.5 mm by 2.5 mm to 2.1 m by 2.1 m. Conductive lines corresponding to the Y axis and spacer dots (not pictured) were printed on polarizer film 602 and conductive lines corresponding to the X axis were printed on a second optically isotropic transparent substrate. As explained above, the spacer dots may be printed on either of the two films.

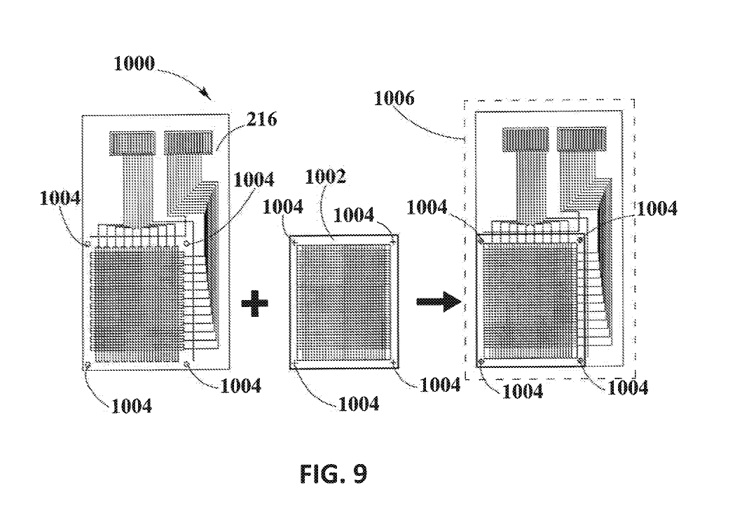

FIG. 9 is an embodiment of an alignment method 1000 used to match the position of the touch sensor 216 and black matrix 1002. In this particular embodiment touch sensor 216 and black matrix 1002 are aligned using registration marks 1004. For an optimal optical performance of the touch screen, touch sensor 216 and black matrix 1002 should be roughly the same size and shape and be properly aligned. As an example we can see aligned structure 1006. Any other known means of alignment may be implemented to substitute the method here illustrated.

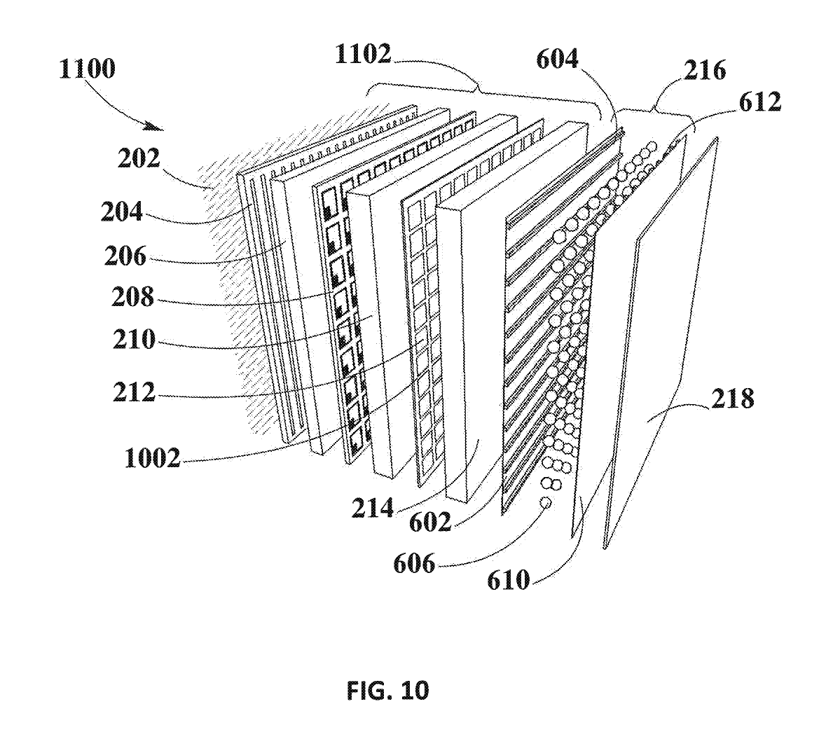

FIG. 10 shows isometric view 1100 of touch screen structure 200 shown in FIG. 2. In this figure we can see LCD 1102, comprising light source 202, first polarizer 204, first glass substrate 206, TFT 208 layer, liquid crystal cells 210, black matrix 1002 embedded on RGB filter 212 and second glass substrate 214. A first polarizer 204 is disposed on light source 202. The TFT layer 208 is disposed on first glass substrate 206 and liquid crystal cells 210 are disposed on top of the TFT layer 208. The RGB filter 212 is disposed on liquid crystal cells 210 and has embedded black matrix 1002. The second glass substrate 214 is disposed on the RGB filter 212. The touch screen structure also comprises touch sensor 216. Touch screen sensor 216 comprises a first plurality of conductive lines 604 printed on polarizer film 602, spacer dots 606, and a second substrate 610. The second substrate 610 comprises a second plurality of conductive lines 612. In some embodiments, on top of touch sensor 216, a cover film 218 may be placed. Alternatively, a hard coating may be applied on the outer surface of touch sensor 216 to replace cover film 218.

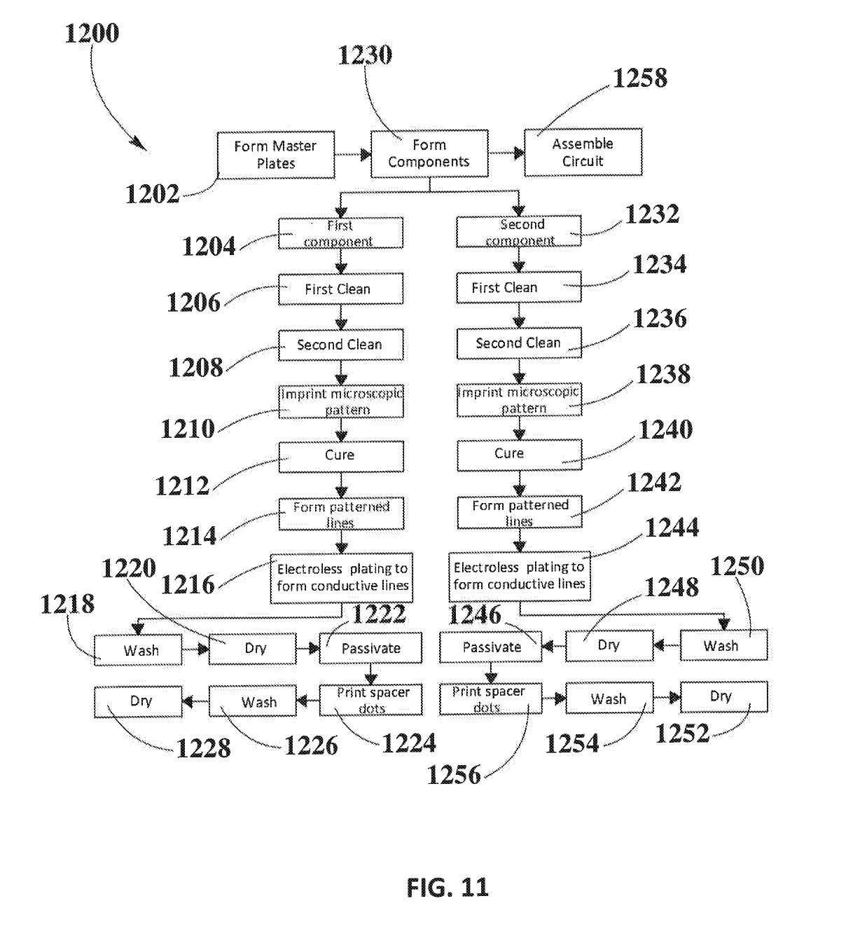

FIG. 11 is an embodiment of a method 1200 of manufacturing resistive touch sensors. Master plates, which may be referred to as flexo-masters, are created by master plate creation process or purchased 1202. In an embodiment, the flexo-masters are created as in FIG. 3, A first and a second component are formed by forming processes 1230. The first component 1204 may comprise a substrate, for example, a polarizing film, that is cleaned at cleaning station 1206. In an embodiment, the substrate may also be cleaned in a subsequent, second cleaning at cleaning station 1208. The cleanings at cleaning station 1206 and cleaning station 1208 may be performed, for example, by at least one of a plasma cleaning process, an elastomeric cleaning process, an ultrasonic cleaning process, a high electric ozone field generator, a web cleaning, or a water wash. In some embodiments, the same cleaning method may be used at both cleaning stations 1206 and 1208. In some embodiments, a different cleaning method may be used at both cleaning stations 1206 and 1208. A microscopic pattern may be printed by a printing station 1210 on one side of the substrate in a first printing process. In an embodiment, the microscopic pattern printed at station 1210 by a first master plate using, for example, UV curable ink. In an embodiment, the microscopic pattern may comprise lines having a width of 2-35 microns. The first printing process may be followed by curing at curing station 1212. In an embodiment, the curing at curing station 1212 may comprise ultraviolet light curing. In an alternate embodiment, the curing at curing station 1212 may comprise heating in an oven or furnace. The printed substrate may be exposed to electroless plating at plating station 1216 wherein conductive lines are formed in the shape of the pattern printed and cured at curing stations 1210 and 1212. A layer of conductive material may be deposited on to the microscopic pattern at plating station 1216. The conductive material comprise, for example, copper (Cu), silver (Ag), gold (Au), nickel (Ni), tin (Sn) and Palladium (Pd). In an embodiment, at washing station 1218 the first substrate may be washed subsequent to electroless plating at plating station 1216. The first substrate may be dried at drying station 1220, and, in some embodiments the first substrate is passivated at passivation station 1222. A second printing process may print spacer dots at printing station 1224, wherein a pattern of microstructural spacers may be printed on the same side of the substrate as the conductive pattern. The microstructural spacer pattern printed at printing station 1224 may be printed using a second master plate and may use UV curable ink. In an embodiment, the spacer pattern printed at printing station 1224 may have a radius between 40-80 microns and a height between 15 microns-500 nanometers. The substrate may then be washed at wash station 1226 and dried at drying station 1228.

In a parallel process 1232, following steps 1234-1256 which are similar to steps 1206-1228 discussed above, a second component is created. In an embodiment, the second component is created using a second substrate (not pictured). In some embodiments, this second substrate may be an optically isotropic transparent film such as cellulose triacetate, acrylic, or similar polymers. In an embodiment, spacer dots may be printed at printing station 1252 instead of or in addition to the spacer dots printed at printing station 1224.

The first and the second substrate may be assembled at assembly station 1258 to form a resistive touch sensor. In some embodiments, the assembly at assembly station 1258 may proceed as described in FIG. 6. In an embodiment, the assembly proceeds so that both conductive patterns are aligned, facing each other and separated by the small gap created by spacer dots printed at printing stations 1224 and/or 1252. The resulting structure would be an X-Y matrix resistive touch sensor, where each of the intersections of the conductive lines forms a normally open push button switch, as illustrated in FIG. 6.

It is understood that the detail drawings and specific examples given describe exemplary embodiments of the present invention and are for the purpose of illustration. The apparatus and method disclosed herein are not limited to the precise details and conditions disclosed. The present method may be applied to electronic devices with touch sensitive features. Such an electronic device may include but is not limited to: a display device, such as a projection device, a computing device, a computer display, a portable media player, etc. As an example the electronic device, such as a display device, may include but is not limited to televisions, monitors and projectors that may be adapted to displays images, including text, graphics, video images, still images, presentations, etc. The following is a non-exhaustive list of exemplary image devices: Cathode ray tubes (CRTs), projectors, flat panel liquid crystal displays (LCDs), LED systems, OLED systems, plasma systems, electroluminescent displays (ELDs), field emissive displays (FEDs).

It also should be understood that numerous modifications may be made to these illustrative embodiments without departing from the spirit and scope of the present invention as defined by the following claims.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method for manufacturing a resistive touch sensor circuit comprising:
printing, by a first master plate using a first ink, a first pattern on a first side of a substrate, and wherein the first pattern comprises a first plurality of lines;
depositing at least one layer of a conductive material on the first pattern, wherein the layer is deposited by electroless plating;
printing, by a second master plate using a second ink, a second pattern on the first side of the first substrate, and wherein the second pattern comprises a second plurality of lines;
depositing at least one layer of the conductive material on the second pattern, wherein the layer is deposited by electroless plating;
printing, by a third master plate using a third ink, on at least one of the first or the second patterns, a plurality of spacer dots.

2. The method of claim 1, wherein the thickness of the substrate is between 1 micron-1 mm.

3. The method of claim 2, wherein the plurality of spacer dots have a diameter of 1 micron-25 microns and a height of 1 micron-25 microns.

4. The method of claim 2, wherein the plurality of spacer dots have a diameter of 5 microns-10 microns, and a height of 3 microns-5 microns.

5. The method of claim 3, further comprising disposing a hard coating, wherein the hard coating comprises a highly crosslinked acrylic-coated film.

6. The method of claim 3, further comprising disposing a cover film on the conductive material on the first pattern, wherein the cover film is a PET film.

7. The method of claim 6, wherein disposing the film comprises disposing triacetyl cellulose with a thickness up to 200 microns.

8. The method of claim 1, further comprising cleaning the substrate by at least one of a plasma cleaning process, an elastomeric cleaning process, an ultrasonic cleaning process, a high electric ozone field generator, a web cleaning, or a water wash.

9. The method of claim 1, further comprising printing the plurality of spacer dots using the third ink that has a viscosity between 200-2000 cps.

10. The method of claim 1, wherein printing the first pattern comprises printing a first plurality of lines wherein each of the plurality of lines is from 2-35 microns wide.

11. The method of claim 1, wherein the first and the second inks contain a plating catalyst.

12. The method of claim 12, wherein the first and the second inks contain different plating catalysts.

13. The method of claim 1, further comprising printing the plurality of spacer dots using the third ink that comprises organic-inorganic nanocomposites

14. The method of claim 13, wherein the nanocomposites comprise at least one of methyl tetraethylorthosilicate or glycidopropyltrimetoxysilane.

15. The method of claim 13, further comprising printing the plurality of spacer dots using the third ink that comprises a photoinitiator and at least one of silica sols, silica powders, ethyl cellulose, and hydroxypropyl.

16. The method of claim 13, further comprising printing the plurality of spacer dots using the third ink that comprises at least one of titanium dioxide (TiO2), barium titanium dioxide (BaTiO), silver (Ag), nickel (Ni), molybdenum (Mo) and platinum (Pt).

17. A resistive touch sensor comprising:
a first substrate and a second substrate,
wherein the first substrate comprises a polarizer film, wherein a first plurality of lines are printed by a first master plate on a first side of the first substrate, and wherein a set of spacers are printed by a second master plate on the first side of the first substrate;
wherein the second substrate comprises an optically isotropic transparent film,
wherein a second plurality of lines are printed by a third master plate on a first side of the second substrate;
wherein the first and the second substrates each comprise an x and a y axis along a surface plane of the first sides that contain the first and the second pluralities of lines;
wherein the first plurality of lines is printed along the x-axis of the first substrate, and wherein the second plurality of lines is printed along the y-axis of the second substrate;
plating the first and the second plurality of lines by electroless plating; and
an adhesive promoting agent, wherein the adhesive promoting agent is disposed between the first side of the first substrate and first side of the second substrate, and wherein the first and the second substrates are assembled to form an x-y grid.

18. The resistive touch sensor of claim 17, wherein the cross-sectional geometry of the first and the second plurality of lines is at least one of a semicircle, a trapezoid, a triangle, a rectangle, or a square.

19. The resistive touch sensor of claim 17, wherein at least one cross-sectional geometry of the first plurality of lines is different than at least one cross-sectional geometry of the second plurality of lines.

20. The resistive touch sensor of claim 17, wherein a conductive material is used to print the first and the second set of conductive lines, wherein the conductive material comprises copper, silver, gold, nickel, tin, and palladium, and wherein the conductive material used to print the first set of conductive lines and the second set of conductive lines are the same.

21. The resistive touch sensor of claim 17, wherein a conductive material is used to print the first and the second set of conductive lines, wherein the conductive material comprises copper, silver, gold, nickel, tin, and palladium, and wherein the conductive material used to print the first set of conductive lines and the second set of conductive lines are different.

22. The resistive touch sensor of claim 17, wherein a plurality of spacers is printed on the substrate on the same side as at least one of the first or the second plurality of lines.

23. The resistive touch sensor of claim 22, wherein the thickness of the adhesive layer is up to the height of the plurality of spacers.

24. A display system comprising:
a liquid crystal display unit;
a resistive touch sensor comprising:
an inner and an outer surface, wherein the inner surface is disposed on the second glass substrate;
wherein the resistive touch sensor further comprises a first substrate comprising a first set of conductive lines, a polarizer film, a plurality of spacer dots, and a second substrate comprising a second set of conductive lines; and
wherein the first and the second set of printed lines are printed using a flexographic printing process and wherein the first and the second set of printed lines are plated with conductive material in an electroless plating process.

25. The touch screen sensor of claim 24 further comprising a cover film, wherein the cover film is disposed on the resistive touch sensor.

26. The touch screen sensor of claim 24 further comprising a hard coating, wherein the hard coating is disposed on the outer surface of the touch sensor.

27. The touch screen sensor of claim 24 wherein the black matrix comprises at least one of chrome and resin, and wherein the black matrix was formed on glass substrate.

28. The touch screen sensor of claim 24, wherein the lighting system creates a uniform distribution of the light emitted from the light source to the polarizer film
